(19) United States
(12) Patent Application Publication
(10) Pub. No.: US 2026/0045285 A1
(43) Pub. Date: Feb. 12, 2026

(54) DEVICE INCLUDING MEMORY CELLS STORING MULTI-BIT DATA AND AN OPERATION METHOD THEREOF

(71) Applicant: SK hynix Inc., Gyeonggi-do (KR)

(72) Inventors: Do Young KIM, Gyeonggi-do (KR); Sun Beom LEE, Gyeonggi-do (KR); Seong Ho CHOI, Gyeonggi-do (KR)

(21) Appl. No.: 19/004,450

(22) Filed: Dec. 30, 2024

(30) Foreign Application Priority Data
Aug. 6, 2024 (KR) 10-2024-0104551

(51) Int. Cl. G11C 8/08; G11C 7/06; G11C 7/10; G11C 7/22; G11C 11/56; G11C 17/16; G11C 17/18

(52) U.S. Cl. CPC G11C 8/08; G11C 7/1051; G11C 7/222; G11C 11/56; G11C 7/06; G11C 17/16; G11C 17/18

(57) ABSTRACT

A semiconductor device includes a memory cell array and a control circuit. The memory cell array includes a plurality of memory cells. Each memory cell is coupled to a ground voltage node, a single bit line, and one of plural word lines for storing multi-bit data. The control circuit is configured to activate the plural word lines to read the multi-bit data stored in each memory cell.

### CROSS-REFERENCE TO RELATED APPLICATIONS

This patent application claims the benefit of priority under 35 U.S.C. § 119(a) to Korean Patent Application No. 10-2024-0104551, filed on Aug. 6, 2024, the entire disclosure of which is incorporated herein by reference.

### TECHNICAL FIELD

One or more embodiments of the present disclosure described herein relates to a semiconductor device, and more particularly, to a device and an operating method including a memory cell configured to store multi-bit data.

### BACKGROUND

Semiconductor devices such as a memory device, a controller, and a central processing unit (CPU) have been developed to input and output data or signals at high speed. The semiconductor devices are designed to process a greater amount of data, but integration degrees of the semiconductor devices are increased. The semiconductor devices may include at least one of volatile memory cells and non-volatile memory cells. It may be necessary to store more data in a smaller area, in order to increase the integration of such semiconductor devices.

### BRIEF DESCRIPTION OF THE DRAWINGS

The description herein makes reference to the accompanying drawings wherein like reference numerals refer to like parts throughout the figures.

FIG. 1 illustrates a memory device according to an embodiment of the present disclosure.

FIG. 2 illustrates a memory device according to an embodiment of the present disclosure.

FIG. 3 illustrates a memory device according to an embodiment of the present disclosure.

FIG. 4 illustrates a memory device according to an embodiment of the present disclosure.

FIG. 5 illustrates an operating method of the memory device described in FIG. 4.

### DETAILED DESCRIPTION

Various embodiments of the present disclosure are described below with reference to the accompanying drawings. Elements and features of this disclosure, however, may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components e.g., an interface unit, circuitry, etc.

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational, e.g., is not turned on nor activated. Examples of block/unit/circuit/component used with the “configured to” language include hardware, circuits, memory storing program instructions executable to implement the operation, etc. Additionally, “configured to” can include a generic structure, e.g., generic circuitry, that is manipulated by software and/or firmware, e.g., an FPGA or a general-purpose processor executing software to operate in a manner that is capable of performing the task(s) at issue. “Configured to” may also include adapting a manufacturing process, e.g., a semiconductor fabrication facility, to fabricate devices, e.g., integrated circuits that are adapted to implement or perform one or more tasks.

As used in this disclosure, the term ‘machine,’ ‘circuitry’ or ‘logic’ refers to all of the following: (a) hardware-only circuit implementations such as implementations in only analog and/or digital circuitry and (b) combinations of circuits and software and/or firmware, such as (as applicable): (i) to a combination of processor(s) or (ii) to portions of processor(s)/software including digital signal processor(s), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘machine,’ ‘circuitry’ or ‘logic’ applies to all uses of this term in this application, including in any claims. As a further example, as used in this application, the term ‘machine’, ‘circuitry’ or ‘logic’ also covers an implementation of merely a processor or multiple processors or a portion of a processor and its (or their) accompanying software and/or firmware. The term ‘machine’, ‘circuitry’ or ‘logic’ also covers, for example, and if applicable to a particular claim element, an integrated circuit for a storage device.

As used herein, the terms ‘first’, ‘second’, ‘third’, and so on are used as labels for nouns that they precede, and do not imply any type of ordering, e.g., spatial, temporal, logical, etc. The terms ‘first’ and ‘second’ do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term ‘based on’ is used to describe one or more factors that affect a determination. This term does not foreclose additional factors that may affect determination. The determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

An embodiment of the present disclosure provides a semiconductor device or memory device including a non-volatile memory cell capable of storing multi-bit data and an operating method thereof.

In addition, an embodiment of the present disclosure provides a device and a method capable of reducing a size of a Read Only Memory (ROM) device by allowing each memory cell included in the ROM device to store multi-bit data.

An embodiment of the present disclosure provides a semiconductor device, including a memory cell array comprising a plurality of memory cells, each memory cell coupled to a ground voltage node, a single bit line, and one of plural word lines for storing multi-bit data; and a control circuit configured to activate the plural word lines to read the multi-bit data stored in each memory cell.

The memory cell can include a single transistor of which a gate is coupled to one of the plural word lines and the ground voltage node.

The single transistor can include a source and a drain. One of the source and the drain can be coupled to the ground voltage node while the other of the source and the drain can be coupled to the bit line.

The multi-bit data can include two-bit data when a number of the plural word lines is three.

The control circuit can be configured to determine whether to activate the plural word lines based on a pair of word line input signals corresponding to a row address.

The pair of word line input signals can include a one-cycle clock signal including one of a logical high level and a logical low level; and an inversion signal of the one-cycle clock signal.

The control circuit can include six transistors of which gates receive the pair of word line input signals. The six transistors can form three pairs, each pair arranged between a power supply voltage line and one of the power supply voltage line or the ground voltage node. Each of the three pairs can be connected to each of the plural word lines.

The control circuit can be configured to: read first data output to the bit line from a first memory cell, among the memory cells, which is coupled to a first word line among the plural word lines; read second data output to the bit line from a second memory cell, among the memory cells, which is coupled to a second word line among the plural word lines; read third data output to the bit line from a third memory cell, among the memory cells, which is coupled to a third word line among the plural word lines; and read fourth data output to the bit line from a fourth memory cell, among the memory cells, which is coupled to the ground voltage node.

The memory cells, the plural word lines, and the ground voltage node can be arranged in a first direction, and the bit line can be arranged in a second direction perpendicular to the first direction.

In another embodiment, a memory device can include a memory cell array in which a plurality of memory cells are arranged in row and column directions, each memory cell coupled to a single bit line and one of a ground voltage node and plural sub word lines; and a control circuit configured to output multi-bit data to each of bit lines from each of plural first memory cells corresponding to a row address for the memory cell array based on a one-cycle clock signal input through a word line corresponding to the row address.

The memory cell can be a non-volatile memory cell including a single transistor of which gate is coupled to one of the ground voltage node and the plural sub word lines.

The single transistor can include a source and a drain. One of the source and the drain can be coupled to the ground voltage node while the other of the source and the drain can be coupled to the bit line.

The multi-bit data can include two-bit data when a number of the plural sub word lines is three.

The control circuit can be configured to determine whether to activate the plural sub word lines based on the one-cycle clock signal and an inversion signal of the one-cycle clock signal.

The control circuit can include six transistors of which gates receive the one-cycle clock signal and the inversion signal of the one-cycle clock signal. The six transistors can form three pairs, each pair arranged between a power supply voltage line and one of the power supply voltage line or the ground voltage node. Each of the three pairs is connected to each of the plural sub word lines.

The control circuit can be arranged at each row of the memory cell array.

The control circuit can be configured to read first data output to the bit line from a first memory cell, among the memory cells, which is coupled to a first sub word line among the plural word lines; read second data output to the bit line from a second memory cell, among the memory cells, which is coupled to a second sub word line among the plural sub word lines; read third data output to the bit line from a third memory cell, among the memory cells, which is coupled to a third sub word line among the plural word lines; and read fourth data output to the bit line from a fourth memory cell, among the memory cells, which is coupled to the ground voltage node.

In another embodiment, a method for operating a semiconductor device can include receiving a one-cycle clock signal and an inversion signal of the one-cycle clock signal, which correspond to a row address; activating plural word lines based on the one-cycle clock signal and the inversion signal of the one-cycle clock signal; and sensing multi-bit data from memory cells coupled to one of the plural word lines and a ground voltage node.

In the method, a number of the plural word lines can be three, the multi-bit data can include two-bit data, and each of the memory cells can include a single transistor of which a gate is coupled to one of the plural word lines and the ground voltage node.

The sensing the multi-bit data can include reading first data output to the bit line from a first memory cell, among the memory cells, which is coupled to a first word line among the plural word lines; reading second data output to the bit line from a second memory cell, among the memory cells, which is coupled to a second word line among the plural word lines; reading third data output to the bit line from a third memory cell, among the memory cells, which is coupled to a third word line among the plural word lines; and reading fourth data output to the bit line from a fourth memory cell, among the memory cells, which is coupled to the ground voltage node.

These and other features and advantages of the invention will become apparent from the detailed description and the accompanying drawings of embodiments of the present disclosure. Embodiments will now be described with reference to the accompanying drawings, wherein like numbers reference like elements.

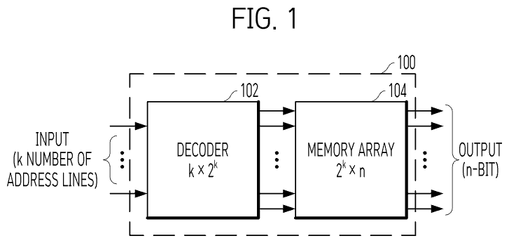

FIG. 1 illustrates a memory device 100 according to an embodiment of the present disclosure.

Referring to FIG. 1, the memory device 100 can include a decoder 102 and a memory array 104. The memory array 104 can be substantially the same as a cell array in which a plurality of memory cells is arranged in row and column directions. The decoder 102 can control a row (e.g., a word line) and a column (e.g., a bit line) of the memory array 104, which correspond to an address (e.g., one of 2k addresses corresponding to k address lines) input from the outside (e.g., an external device). In response to the control of the decoder 102, the memory array 104 can output data (e.g., an output of n bits) output from a corresponding location of the memory array 104 to the outside. The memory device 100 can include a device that is configured to store a program and data to be processed or store a result after processing.

According to an embodiment, the memory device 100 can be divided into a main memory and an auxiliary memory. For example, the main memory can include a Random Access Memory (RAM), a Read Only Memory (ROM), a Programmable Logic Device (PLD), or the like. The auxiliary memory can include a magnetic tape, a floppy disk, a hard disk, a laser disk, a Solid State Drive (SSD), or the like.

According to an embodiment, the memory cell in the memory device 100 can store 1-bit data (‘0’ or ‘1’) or multi-bit data (e.g., 2-bit data, 3-bit data, 4-bit data, or etc.). A data storage capacity of the memory device 100 can be calculated or determined based on the number of memory cells and the number of bits of data stored in each memory cell. In addition, operating performance of the memory device 100 can be affected by the speed of storing or recording data or information in the memory device 100 and reading data or information stored in the memory device 100.

According to an embodiment, the memory device 100 can include a RAM that can store a user-written program or data in any memory location, read the user-written program or data whenever necessary, and freely change or modify the user-written program or data. The RAM is classified as volatile memory because information or data is lost when there is no power. The RAM can include a Static RAM (SRAM) and a Dynamic RAM (DRAM).

According to an embodiment, the memory device 100 can include a ROM that can only read recorded data and have the characteristic that stored data might be changed and the stored data does not disappear even after the power is turned off. The ROM can include a mask ROM that could not change data stored once, a Programmable ROM (PROM) that could be programmed by a user to write data (then, the programmed data could not be changed), an Erasable PROM (EPROM) that could erase data written once, or the like.

The ROM can be configured in various forms. For example, the memory array 104 can be configured with a plurality of logical OR gates. The number of logical OR gates can be determined depending on the number of input addresses and the number of bits of output data. According to an embodiment, the ROM can be configured with an internal electronic fuse line that could be programmed with a special pattern structure. Once the electronic fuse lines in the memory array 104 are programmed (or set) in a particular pattern, the pattern could be maintained regardless of supply or absence of power, so that programmed data could be stored and output. Referring to FIG. 1, when k inputs are applied to the decoder 102 in the memory device 100, one of the 2\hat{ }k decoder outputs becomes ‘1’ (e.g., a word line corresponding to a row address becomes ‘1’). The output of the decoder 102 can cause data stored in a single row of the memory array 104 to be output.

According to an embodiment, the ROM is mainly used to store fixed data or a program. The data or program could not be changed after programmed. Multiple bits of data could be stored in a single memory cell included in the ROM. For example, the ROM can store data in units of bytes (8 bits), words (16 bits), or larger units such as 32 bits or 64 bits in a single memory cell. For this purpose, each memory cell can include multiple electronic fuse lines, multiple transistors, or multiple logic gates. This configuration may have a limitation in reducing a size of the memory array 104. For example, if each memory cell includes eight transistors to store byte-unit data, it might not be substantially different from storing byte-unit data in eight memory cells, each memory cell including a single transistor.

While the ROM has the characteristic of being able to store and read multi-bit data, it is necessary to store multiple bits of data in a small number of components (e.g., a memory cell) in order to reduce the size (e.g., area) of the ROM. According to an embodiment, the memory array 104 can include plural memory cells, each memory cell including a single transistor, arranged in the row and column directions. The transistor included in each memory cell can have a specific pattern corresponding to a multi-bit value of the data to be stored. Hereinafter, the internal structure and operation method of the ROM included in a semiconductor device such as the memory device 100 according to an embodiment of the present disclosure will be described.

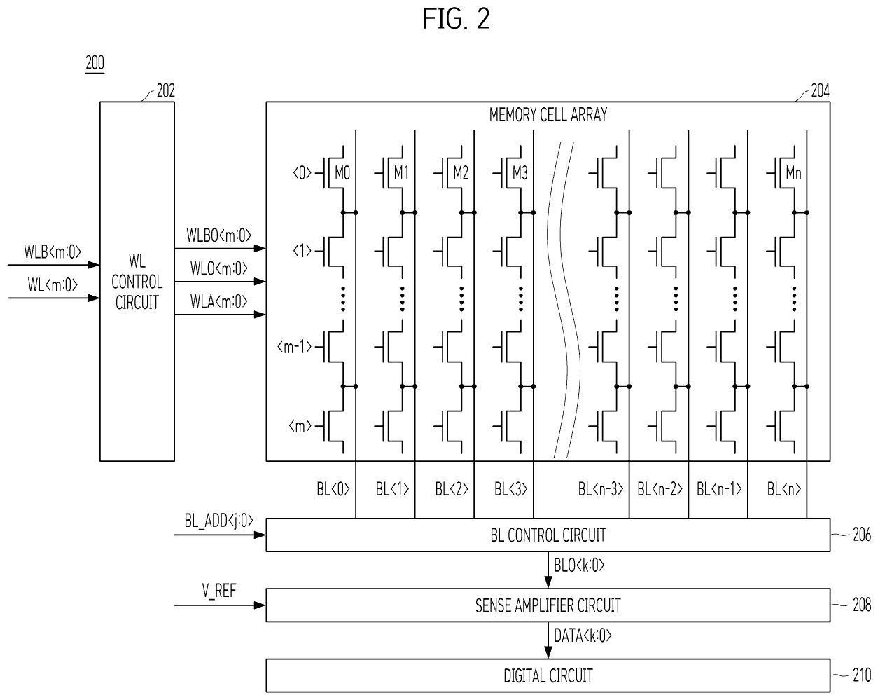

FIG. 2 illustrates a memory device according to an embodiment of the present disclosure.

Referring to FIG. 2, the memory device 200 can include a word line (WL) control circuit 202, a memory cell array 204, a bit line (BL) control circuit 206, a sense amplifier circuit 208, and a digital circuit 210.

When a pair of word lines WL<m:0>, WLB<m:0> corresponding to a row address are input, the word line control circuit 202 can activate plural sub word lines WLA<m:0>, WLBO<m:0>, WLO<m:0> corresponding to the row address input to the memory device 200.

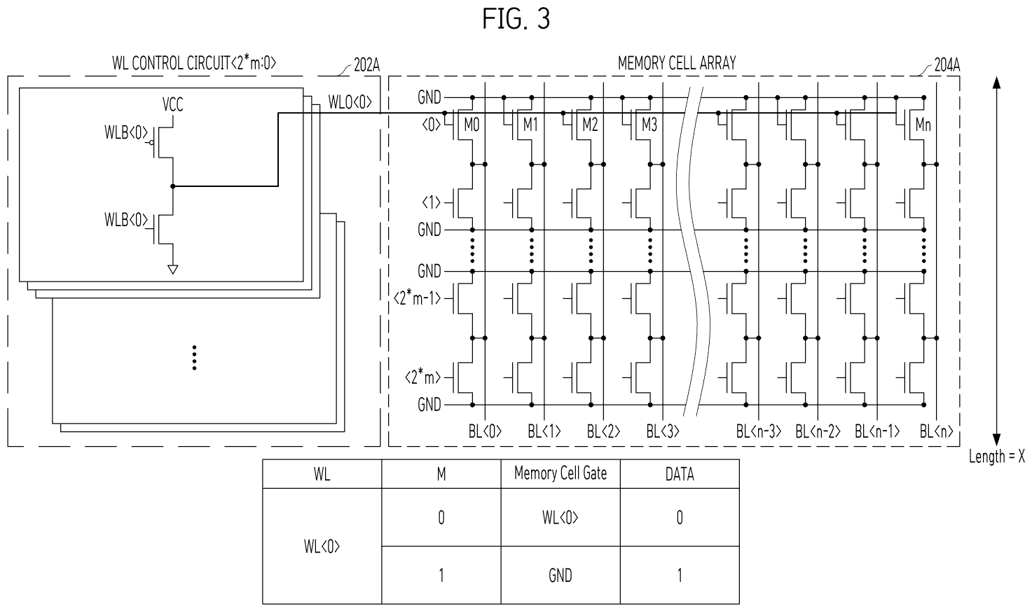

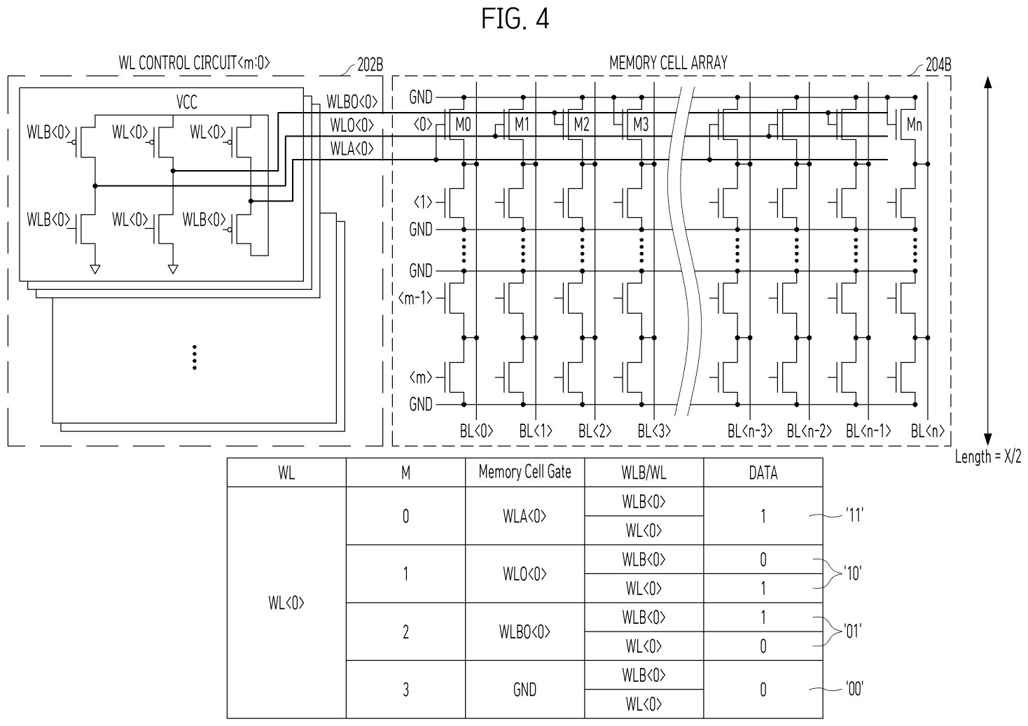

The memory cell array 204 can include a plurality of memory cells M0, M1, M2, M3, . . . , Mn. The plurality of memory cells M0, M1, M2, M3, . . . , Mn can be arranged in the row and column directions. Each of the plurality of memory cells M0, M1, M2, M3, . . . , Mn can store 1-bit or multi-bit data. Each of the plurality of memory cells M0, M1, M2, M3, . . . , Mn can include a single transistor of which a gate could be connected to at least one of plural sub word lines WLA<m:0>, WLBO<m:0>, WLO<m:0> and a ground voltage node. In addition, each of the plurality of memory cells M0, M1, M2, M3 can be connected to each of plural bit lines BL<0:n>. A specific description of the word line control circuit 202 that activates the plurality of sub word lines WLA<m:0>, WLBO<m:0>, WLO<m:0> and the plurality of memory cells M0, M1, M2, M3, . . . , Mn that can individually store 1-bit or multi-bit data will be described later with reference to FIGS. 3 and 4.

The bit line control circuit 206 can activate or deactivate at least some of the plural bit lines BL<0:n> arranged in the memory cell array 204 based on a bit line address BL_ADD<j:0>. The bit line address BL_ADD<j:0> can correspond to a column address input to the memory device 200.

The sense amplifier circuit 208 can sense or detect data by comparing a reference voltage V_REF with a potential of the activated bit line BL<k:0>. For example, when all of the plurality of bit lines BL<0:n> are activated, the sense amplifier circuit 208 can read data from all memory cells connected to the sub word lines activated in response to the row address. When some bit lines BL<k:0> among the plurality of bit lines BL<0:n> are activated, the sense amplifier circuit 208 can read data DATA<k:0> from memory cells connected to the activated bit lines BL<k:0> among all memory cells connected to the sub word lines activated in response to the row address.

According to an embodiment, the row address and column addresses input to the memory device 200 can correspond to the k inputs described in FIG. 1. The word line control circuit 202 can be understood as a component included in the decoder 102 described in FIG. 1, or as an additional component arranged between the decoder 102 and the memory array 104.

According to an embodiment, the data DATA<k:0> output from the sense amplifier circuit 208 can be transferred to the digital circuit 210.

According to an embodiment, the digital circuit 210 can process or handle the data DATA<k:0> or perform a mathematical or logical operation based on the data DATA<k:0>.

FIG. 3 illustrates a memory device according to an embodiment of the present disclosure. Specifically, FIG. 3 illustrates an embodiment in which each memory cell included in the memory device stores 1-bit data.

Referring to FIG. 3, a memory cell array 204A can include a plurality of memory cells arranged in the row and column directions. Each memory cell can include one transistor. A gate of the transistor can be connected to a first word line WL0<0> or a ground voltage node GND. One of the source and drain regions of the transistor can be connected to one of the bit lines BL<0:n>, and the other of the source and drain regions can be connected to the ground voltage node GND.

Specifically, among the plurality of memory cells connected to the first word line WL0<0>, a first memory cell M0 connected to a first bit line BL<0> can include a transistor whose gate is connected to the first word line WL0<0>. Among the plurality of memory cells connected to the first word line WL0<0>, a second memory cell M1 connected to a second bit line BL<1> can include a transistor whose gate is connected to the ground voltage node GND rather than the first word line WL0<0>. The first data stored in the first memory cell M0 and second data stored in the second memory cell M1 are different from each other. Based on this structure, each of the plurality of memory cells included in the memory cell array 204A can store 1-bit data. The stored data could be kept or maintained regardless of whether power is supplied, because this structure is not changed regardless of whether the power is supplied.

The word line control circuit 202A coupled to the memory cell array 204A can include a plurality of control circuits. A first control circuit included in the word line control circuit 202A can determine whether to activate the first word line WL0<0> based on input through the pair of word lines WL<m:0>, WLB<m:0>. The first control circuit can include a pair of transistors, each of which gate is coupled to a pair of word lines WL<m:0>, WLB<m:0> as gate inputs. The pair of transistors can be arranged between a power supply voltage node VCC and a ground voltage node GND.

For example, the first control circuit can include a PMOS transistor of which a gate is connected to an input word line WL<0>, and an NMOS transistor of which a gate is connected to an inverted signal WLB<0> of the input word line WL<0>. For example, when the input word line WL<0> is a logic low level (‘0’), the first word line WL0<0> can be activated. The transistor in the first memory cell M0 connected to the first word line WL0<0> can be turned on. Because one side of the transistor in the first memory cell M0 is connected to the ground voltage node GND, the potential of the first bit line BL<0> becomes lowered. The sense amplifier circuit 208 described in FIG. 2 can sense or detect that the potential of the first bit line BL<0> becomes lowered, and then determine that the data stored in the first memory cell M0 is ‘0’.

The second memory cell M1 can include a transistor whose gate is connected to the ground voltage node GND. Even if the first word line WL0<0> is activated, the transistor in the second memory cell M1 can maintain a turn-off state, and thus the potential of the second bit line BL<1> might not be lowered. The sense amplifier circuit 208 can detect that the potential of the second bit line BL<1> might be not lowered, and thus determine that the data stored in the second memory cell M1 is ‘1’.

Through the above-described scheme or method, while the first word line WL0<0> is activated, the plurality of memory cells (i.e., plural memory cells arranged in a first row of the memory cell array 204A) connected to either the first word line WL0<0> or the ground voltage node GND can output pre-programmed data of ‘1’ or ‘0’.

The size of the memory cell array 204A can vary depending on the size of data to be stored in the memory cell array 204A. Because each memory cell included in the memory cell array 204A can store 1-bit data, a length in the column direction of the memory cell array 204A can be designed to be increased when the size of the data increases. If each memory cell included in the memory cell array 204A can store multi-bit data, the length in the column direction of the memory cell array 204A can be reduced. For example, the length in the column direction of the memory cell array 204A may be ‘X’. If each memory cell in the memory cell array 204A can store 2-bit data, the length in the column direction of the memory cell array 204A can be reduced to ‘X/2’.

FIG. 4 illustrates a memory device according to an embodiment of the present disclosure. Specifically, FIG. 4 illustrates an embodiment in which each memory cell included in the memory device stores multi-bit data. The multi-bit data is described by illustrating 2-bit data.

Referring to FIG. 4, a memory cell array 204B can include a plurality of memory cells arranged in the row and column directions. Each memory cell can include a single transistor, not plural transistors. The gate of the transistor can be connected to a plurality of sub word lines WLA<0>, WLO<0>, WLBO<0> or a ground voltage line GND. One of the source and drain regions of the single transistor can be connected to one of the bit lines BL<0:n>, and the other of the source and drain regions can be connected to the ground voltage line GND. The ground voltage line GND (or ground voltage node) could be referred to as a terminal, a pad, a pin, or a contact connected to a ground voltage (i.e., 0 V).

Specifically, among the plurality of memory cells connected to the first word line WL0<0>, a first memory cell M0 connected to a first bit line BL<0> can include a transistor whose gate is connected to the first sub word line WLA<0>. Among the plurality of memory cells connected to the first word line WL0<0>, a second memory cell M1 connected to a second bit line BL<1> can include a transistor whose gate is connected to the second sub word line WL0<0>. Among the plurality of memory cells connected to the first word line WL0<0>, a third memory cell M2 connected to a third bit line BL<2> can include a transistor whose gate is connected to a third sub word line WLBO<0>. Among the plurality of memory cells connected to the first word line WL0<0>, a fourth memory cell M3 connected to a fourth bit line BL<3> can include a transistor whose gate is connected to the ground voltage line GND rather than to the first to third sub word lines WLA<0>, WLO<0>, WLBO<0>. That is, data stored in the first to fourth memory cells M0 to M3 can be different from each other. Based on this structure, each of the plurality of memory cells included in the memory cell array 204A can store 2-bit data, and the stored data can be kept or maintained regardless of whether power is supplied.

The word line control circuit 202B connected to the memory cell array 204B can include a plurality of control circuits. A first control circuit included in the word line control circuit 202B can activate all of the first to third sub word lines WLA<0>, WLO<0>, WLBO<0> based on input through a pair of word lines WL<m:0>, WLB<m:0>. To this end, the first control circuit can include three pairs of transistors of which gates are individually coupled to each of the pair of word lines WL<m:0>, WLB<m:0> as gate inputs. The three pairs of transistors can be arranged between the power voltage node VCC and either the ground voltage node GND or the power voltage node VCC.

For example, the first control circuit can activate the first sub word line WLA<0> through a pair of transistors including a PMOS transistor and an NMOS transistor of which gates are connected to the inverted signal WLB<0> of the input word line WL<0>. The two PMOS transistors for activating the first sub word line WLA<0> can be arranged between the power supply voltage nodes VCC.

The first control circuit can activate the second sub word line WLO<0> through another pair of transistors including a PMOS transistor and an NMOS transistor of which gates are connected to the inverted signal WLB<0> of the input word line WL<0>. The pair of PMOS and NMOS transistors for activating the second sub word line WLO<0> can be arranged between the power supply voltage node VCC and the ground voltage node.

The first control circuit can activate the third sub word line WLBO<0> through another pair of transistors including a PMOS transistor and an NMOS transistor of which gates are connected to the input word line WL<0>. The pair of PMOS and NMOS transistors for activating the third sub word line WLOB<0> can be placed between the power supply voltage node VCC and the ground voltage node.

The pair of word lines WL<m:0>, WLB<m:0> can be input with a 1-cycle clock signal including a logic high level ‘1’ and a logic low level ‘0’. For example, when the input word line WL<0> is the logic high level ‘1’, the inverted signal WLB<0> of the input word line WL<0> can become the logic low level ‘0’. Because one of the two PMOS transistors arranged between the power supply voltage nodes VCC in the first control circuit is turned on, the first sub word line WLA<0> can become the logical high level ‘1’. When the first sub word line WLA<0> becomes the logical high level ‘1’, the transistor in the first memory cell M0 can be turned on. Because one side of the transistor in the first memory cell M0 is connected to the ground voltage node GND, the potential of the first bit line BL<0> can decrease or go down. The sense amplifier circuit 208 described in FIG. 2 can detect that the potential of the first bit line BL<0> decreases and determine that the data stored in the first memory cell M0 is ‘1’. Thereafter, when the input word line WL<0> becomes the logic low level ‘0’ from the logical high level ‘1’, one of the two PMOS transistors arranged between the power supply voltage nodes VCC in the first control circuit can be turned on. Then, the first sub word line WLA<0> can become a logic high level ‘1’. That is, while a one-cycle clock signal including a logic high level ‘1’ and a logic low level ‘0’ is input as the input word line WL<0>, the first sub word line WLA<0> can become and maintain the logic high level ‘1’. Accordingly, while the one-cycle clock signal is input, the sense amplifier circuit 208 can detect that the potential of the first bit line BL<0> is lowered and determine that first data stored in the first memory cell M0 is ‘1’ (i.e., two-bit data of ‘11’).

In response to the 1-cycle clock signal including the logic high level ‘1’ and the logic low level ‘0’ input through the pair of word lines WL<m:0>, WLB<m:0>, the first control circuit can activate the second sub word line WLO<0>. When the input word line WL<0> is the logic high level ‘1’, the inverted signal WLB<0> of the input word line WL<0> can become the logic low level ‘0’. When the PMOS transistor connected to the inverted signal WLB<0> of the word line WL<0> is turned on, the second sub word line WLO<0> can become the logic high level ‘1’. When the second sub word line WLO<0> is the logic high level ‘1’, the transistor in the second memory cell M1 can be turned on. Because one side of the transistor in the second memory cell M1 is connected to the ground voltage node GND, the potential of the second bit line BL<1> could be lowered. The sense amplifier circuit 208 can detect that the potential of the second bit line BL<1> is lowered and determine that the data stored in the second memory cell M1 is ‘1’. Thereafter, when the input word line WL<0> becomes the logic low level ‘0’ from the logical high level ‘1’, the inverted signal WLB<0> of the word line WL<0> becomes the logic high level ‘1’. When the NMOS transistor connected to the inverted signal WLB<0> of the word line WL<0> is turned on, the second sub word line WLO<0> can become the logic low level ‘0’. When the second sub word line WLO<0> is the logic low level ‘0’, the transistor in the second memory cell M1 is turned off. The sense amplifier circuit 208 can detect that the potential of the second bit line BL<1> does not decrease, and thus determines that the data stored in the second memory cell M1 is ‘0’. Through this operation, in response to the one-cycle clock signal including the logic high level ‘1’ and the logic low level ‘0’ input through the pair of word lines WL<m:0>, WLB<m:0>, second data output from the second memory cell M1 can be determined as two-bit data of ‘10’.

In response to the 1-cycle clock signal including the logic high level ‘1’ and the logic low level ‘0’ input through the pair of word lines WL<m:0>, WLB<m:0>, the first control circuit can activate the third sub word line WLOB<0>. When the input word line WL<0> is the logic high level ‘1’, the NMOS transistor connected to the input word line WL<0> can be turned on, so that the third sub word line WLOB<0> can become the logic low level ‘0’. When the third sub-word line WLOB<0> becomes the logic low level ‘0’, the transistor in the third memory cell M2 can be turned off. The sense amplifier circuit 208 can detect that the potential of the third bit line BL21> does not decrease, and thus determines that the data stored in the third memory cell M2 is ‘0’. Thereafter, when the input word line WL<0> becomes the logical low level ‘0’ from the logical high level ‘1’, the PMOS transistor connected to the input word line WL<0> can be turned on, and thus the third sub word line WLOB<0> can become the logical high level ‘1’. When the third sub word line WLOB<0> is the logical high level ‘1’, the transistor in the third memory cell M2 can be turned on. Because one side of the transistor in the third memory cell M2 is connected to the ground voltage node GND, the potential of the third bit line BL<2> can decrease. The sense amplifier circuit 208 can detect that the potential of the third bit line BL<2> is lowered and determines that the data stored in the third memory cell M2 is ‘1’. Through this operation, in response to the one-cycle clock signal including the logic high level ‘1’ and the logic low level ‘0’ input through the pair of word lines WL<m:0>, WLB<m:0>, third data output from the third memory cell M2 can be determined as two-bit data of ‘01’.

The fourth memory cell M3 can include a transistor whose gate is connected to the ground voltage line GND. Even if the first to third sub word lines WLA<0>, WLO<0>, WLBO<0> are activated, the transistor in the fourth memory cell M3 can maintain a turn-off state, and the potential of the fourth bit line BL<3> would not decrease. Accordingly, while a one-cycle clock signal is input, the sense amplifier circuit 208 can detect that the potential of the fourth bit line BL<3> does not decrease and determines that fourth data stored in the fourth memory cell M3 is ‘0’ (i.e., two-bit data of ‘00’).

Through the above-described operations, in response to the 1-cycle clock signal including the logic high level ‘1’ and the logic low level ‘0’ input through the pair of word lines WL<m:0>, WLB<m:0>, the first to fourth memory cells M0, M1, M2, M3 in the memory cell array 204B can output different 2-bit data (i.e., ‘11’, ‘10’, ‘01’, ‘00’) that are stored or programmed in advance. While a plurality of memory cells in the memory cell array 204B store 2-bit data, the length in the column direction of the memory cell array 204B could be reduced by a half (i.e., Length=X/2) compared to the memory cell array 204A described in FIG. 3.

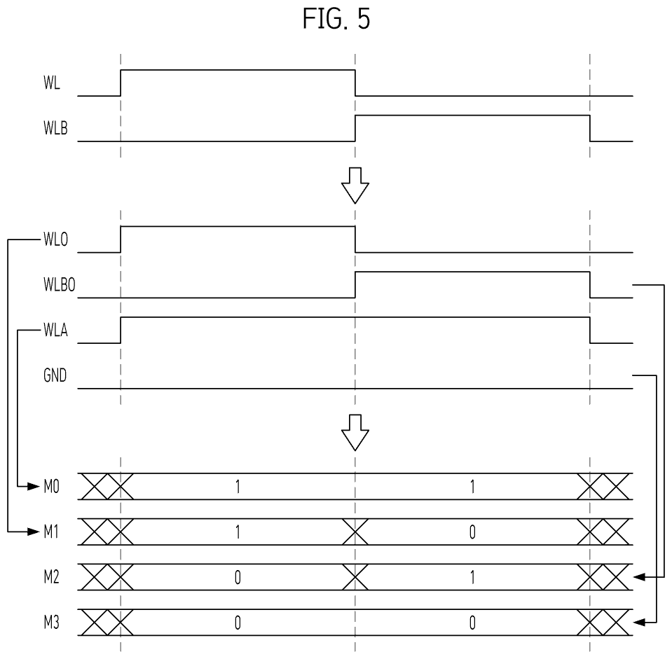

FIG. 5 illustrates an operating method of the memory device described in FIG. 4.

Referring to FIG. 5, a one-cycle clock signal including the logic high level ‘1’ and a logic low level ‘0’ can be input through the pair of word lines WL, WLB. A pair of signals that have an inversion relationship from each other can be input to the word line control circuit 202B through the pair of word lines WL, WLB.

The word line control circuit 202B can activate a plurality of sub word lines WLA, WLO, WLBO in response to the one-cycle clock signal input through the pair of word lines WL, WLB. At this time, the plurality of sub word lines WLA, WLO, WLBO can be activated in different forms. For example, the first sub word line WLA can maintain the logic high level ‘1’ in response to the one-cycle clock signal. The second sub word line WLO can be activated in the same form as the input word line WL. The third sub word line WLOB can be activated in the same form as the inverted signal WLB of the word line WL. The memory cells that are not connected to the plurality of sub word lines WLA, WLO, WLBO can be connected to the ground voltage line GND.

In response to the output of the word line control circuit 202B, different memory cells M0, M1, M2, M3 connected to one of the plurality of sub word lines WLA, WLO, WLBO and the ground voltage line GND in the memory cell array 204B can output different two-bit data (e.g., ‘11’, ‘10’, ‘01’, ‘00’).

Referring to FIGS. 3 to 5, each memory cell including the single transistor can store 1-bit data or multi-bit data. Each memory cell in the memory cell array can store multi-bit data while reducing the size of the memory cell array.

According to an embodiment, a semiconductor device, a memory device, or a memory system can include multiple components including a ROM. The ROM designed for using predetermined data for a preset purpose (e.g., implementation of a preset specific circuit or operation) can be utilized or implemented in the semiconductor device, the memory device, or the memory system. Such a ROM can be arranged in a peripheral region of the semiconductor device, the memory device, or the memory system. The ROM can be mounted for the purpose of assisting an operation of the semiconductor device, the memory device, or the memory system. When storing data of the same amount, the size of the ROM can be reduced by storing multi-bit data in each memory cell. Reducing the size of the ROM included in the peripheral region can help improve the integration of the semiconductor device, the memory device, or the memory system.

According to an embodiment of the present disclosure, by using the 1-cycle clock signal including the logical high level ‘1’ and the logical low level ‘0’ input through the pair of word lines WL, WLB, there is no need to secure an operation margin for separately driving a bit line (e.g., bit line loading, bit line precharging, etc.) in a procedure of sequentially reading the multi-bit data from each memory cell in the memory cell array. Accordingly, the time for reading the multi-bit data programmed in the ROM might not significantly increase.

As above described, a semiconductor device according to an embodiment of the present disclosure can reduce a size of a non-volatile memory device, thereby improving the integration of a semiconductor device including the non-volatile memory device.

In addition, a memory device or a memory system according to an embodiment of the present disclosure can perform an operation of reading multi-bit data from a plurality of memory cells by activating a plurality of word lines based on a one-cycle clock signal corresponding to a row address.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods or operations of the computer, processor, controller, or other signal processing device, are described in detail, the code or instructions for implementing the operations of the method embodiments may transform the computer, processor, controller, or other signal processing device into a special-purpose processor for performing the methods herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, controller, or other signal processing device which is to execute the code or instructions for performing the method embodiments or operations of the apparatus embodiments herein.

The controllers, processors, control circuitry, devices, modules, units, multiplexers, generators, logic, interfaces, decoders, drivers, and other signal generating and signal processing features of the embodiments disclosed herein may be implemented, for example, in non-transitory logic that may include hardware, software, or both. When implemented at least partially in hardware, the controllers, processors, control circuitry, devices, modules, units, multiplexers, generators, logic, interfaces, decoders, drivers, and other signal generating and signal processing features may be, for example, any of a variety of integrated circuits including but not limited to an application-specific integrated circuit, a field-programmable gate array, a combination of logic gates, a system-on-chip, a microprocessor, or another type of processing or control circuit.

When implemented at least partially in software, the controllers, processors, control circuitry, devices, modules, units, multiplexers, generators, logic, interfaces, decoders, drivers, and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods or operations of the computer, processor, microprocessor, controller, or other signal processing device, are described in detail, the code or instructions for implementing the operations of the method embodiments may transform the computer, processor, controller, or other signal processing device into a special-purpose processor for performing the methods described herein.

While the invention has been illustrated and described with respect to the specific embodiments, it will be apparent to those skilled in the art in light of the present disclosure that various changes and modifications may be made without departing from the spirit and scope of the present disclosure as defined in the following claims. Furthermore, the embodiments may be combined to form additional embodiments.

What is claimed is:

1. A semiconductor device comprising:
a memory cell array comprising a plurality of memory cells, each memory cell coupled to a ground voltage node, a single bit line, and one of plural word lines for storing multi-bit data; and
a control circuit configured to activate the plural word lines to read the multi-bit data stored in each memory cell.

2. The semiconductor device according to claim 1, wherein the memory cell comprises a single transistor of which a gate is coupled to one of the plural word lines and the ground voltage node.

3. The semiconductor device according to claim 2, wherein the single transistor comprises a source and a drain, and
wherein one of the source and the drain is coupled to the ground voltage node while the other of the source and the drain is coupled to the bit line.

4. The semiconductor device according to claim 2, wherein the multi-bit data comprises two-bit data when a number of the plural word lines is three.

5. The semiconductor device according to claim 4, wherein the control circuit is configured to determine whether to activate the plural word lines based on a pair of word line input signals corresponding to a row address.

6. The semiconductor device according to claim 5, wherein the pair of word line input signals comprises:
a one-cycle clock signal including one of a logical high level and a logical low level; and
an inversion signal of the one-cycle clock signal.

7. The semiconductor device according to claim 5, wherein the control circuit comprises six transistors of which gates receive the pair of word line input signals,
wherein the six transistors form three pairs, each pair arranged between a power supply voltage line and one of the power supply voltage line or the ground voltage node, and
wherein each of the three pairs is connected to each of the plural word lines.

8. The semiconductor device according to claim 5, wherein the control circuit is configured to:
read first data output to the bit line from a first memory cell, among the memory cells, which is coupled to a first word line among the plural word lines;
read second data output to the bit line from a second memory cell, among the memory cells, which is coupled to a second word line among the plural word lines;
read third data output to the bit line from a third memory cell, among the memory cells, which is coupled to a third word line among the plural word lines; and
read fourth data output to the bit line from a fourth memory cell, among the memory cells, which is coupled to the ground voltage node.

9. The semiconductor device according to claim 1, wherein the memory cells, the plural word lines, and the ground voltage node are arranged in a first direction, and the bit line is arranged in a second direction perpendicular to the first direction.

10. A memory device comprising:
a memory cell array in which a plurality of memory cells are arranged in row and column directions, each memory cell coupled to a single bit line and one of a ground voltage node and plural sub word lines; and
a control circuit configured to output multi-bit data to each of bit lines from each of plural first memory cells corresponding to a row address for the memory cell array, based on a one-cycle clock signal input through a word line corresponding to the row address.

11. The memory device according to claim 10, wherein the memory cell is a non-volatile memory cell comprising a single transistor of which a gate is coupled to one of the ground voltage node and the plural sub word lines.

12. The memory device according to claim 11, wherein the single transistor comprises a source and a drain, and
wherein one of the source and the drain is coupled to the ground voltage node while the other of the source and the drain is coupled to the bit line.

13. The memory device according to claim 11, wherein the multi-bit data comprises two-bit data when a number of the plural sub word lines is three.

14. The memory device according to claim 11, wherein the control circuit is configured to determine whether to activate the plural sub word lines based on the one-cycle clock signal and an inversion signal of the one-cycle clock signal.

15. The memory device according to claim 14, wherein the control circuit comprises six transistors of which gates receive the one-cycle clock signal and the inversion signal of the one-cycle clock signal,
wherein the six transistors form three pairs, each pair arranged between a power supply voltage line and one of the power supply voltage line or the ground voltage node, and
wherein each of the three pairs is connected to each of the plural sub word lines.

16. The memory device according to claim 15, wherein the control circuit is arranged at each row of the memory cell array.

17. The memory device according to claim 10, wherein the control circuit is configured to:
read first data output to the bit line from a first memory cell, among the memory cells, which is coupled to a first sub word line among the plural sub word lines;
read second data output to the bit line from a second memory cell, among the memory cells, which is coupled to a second sub word line among the plural sub word lines;
read third data output to the bit line from a third memory cell, among the memory cells, which is coupled to a third sub word line among the plural sub word lines; and
read fourth data output to the bit line from a fourth memory cell, among the memory cells, which is coupled to the ground voltage node.

18. A method for operating a semiconductor device, the method comprising:
receiving a one-cycle clock signal and an inversion signal of the one-cycle clock signal, which correspond to a row address;
activating plural word lines based on the one-cycle clock signal and the inversion signal of the one-cycle clock signal; and
sensing multi-bit data from memory cells coupled to one of the plural word lines and a ground voltage node.

19. The method according to claim 18, wherein when a number of the plural word lines is three,
the multi-bit data comprises two-bit data, and
wherein each of the memory cells comprises a single transistor of which a gate is coupled to one of the plural word lines and the ground voltage node.

20. The method according to claim 18, wherein the sensing the multi-bit data comprising:
reading first data output to the bit line from a first memory cell, among the memory cells, which is coupled to a first word line among the plural word lines;
reading second data output to the bit line from a second memory cell, among the memory cells, which is coupled to a second word line among the plural word lines;
reading third data output to the bit line from a third memory cell, among the memory cells, which is coupled to a third word line among the plural word lines; and
reading fourth data output to the bit line from a fourth memory cell, among the memory cells, which is coupled to the ground voltage node.
